(19) United States
(12) Patent Application Publication
(10) Pub. No.: US 2025/0344549 A1
(43) Pub. Date: Nov. 6, 2025

(54) SINGLE-PHOTON AVALANCHE DIODE (SPAD) SENSOR, SEMICONDUCTOR STRUCTURE INCLUDING SPAD SENSOR, AND METHOD FOR FORMING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); CHEUNG CHENG, HSINCHU CITY (TW)

(21) Appl. No.: 18/654,018

(22) Filed: May 3, 2024

(51) Int. Cl. H01L 31/0352; H01L 31/02; H01L 31/107; H01L 31/18

(52) U.S. Cl. CPC H10F 77/146; H10F 30/225; H10F 71/00; H10F 77/148; H10F 77/933

(57) ABSTRACT

A semiconductor structure including a SPAD sensor includes a plurality of fin-like structures disposed over a semiconductor substrate, a mesa surrounding the plurality of fin-like structures over the semiconductor substrate, a first well in the semiconductor substrate, a second well in each fin-like structure over the first well, and a doped layer disposed in the plurality of fin-like structures and over the second well.

### BACKGROUND

A single-photon avalanche diode (SPAD) sensor is able to detect incident light at very low intensities, including single photon detection. A SPAD is a photodiode including a p-n junction that operates at a reverse bias above a breakdown voltage. During operation, photo-generated carriers move to a depletion region (i.e., a multiplication junction region) of the p-n junction and trigger an avalanche effect such that a signal current is detected with high timing accuracy. Further, the avalanche is quickly quenched to prevent damage to the p-n junction. The p-n junction is then reactivated by recharging the junction to a voltage greater than the breakdown voltage.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a SPAD sensor in accordance with aspects of the present disclosure.

FIGS. 2 to 10 are schematic drawings showing various stages in a formation of a SPAD sensor in accordance with aspects of the present disclosure in one or more embodiments, wherein FIGS. 9A and 9B show various embodiments of a stage in the formation of the SPAD sensor.

FIG. 11A is a plan view of the semiconductor substrate after formation of a plurality of fin-like structures and a mesa; and FIG. 11B is a cross-sectional view taken along a line I-I′ of FIG. 11A.

FIG. 12A is a plan view of the semiconductor substrate after formation of a plurality of fin-like structures and a mesa; and FIG. 12B is a cross-sectional view taken along a line II-II′ of FIG. 12A.

FIG. 13A is a plan view of the semiconductor substrate after formation of a plurality of fin-like structures and a mesa; FIG. 13B is a cross-sectional view taken along a line III-III′ of FIG. 13A; and FIG. 13C is a cross-sectional view taken along a line IV-IV′ of FIG. 13A.

FIG. 14 is a flowchart representing a method for forming a semiconductor structure including a SPAD sensor in accordance with aspects of the present disclosure.

FIGS. 15 to 25B are schematic drawings showing various stages in a formation of a semiconductor structure including a SPAD sensor in accordance with aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature on or over a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of brevity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

The present disclosure provides a SPAD sensor having a plurality of fin-like structures where a p-n junction is formed. In some embodiments, the p-n junction is formed in the fin-like structures, which have a wavy or non-planar configuration. Accordingly, an area of the p-n junction is increased. As a result, a quantity of photo-generated carriers generated in the p-n junction per unit area is therefore increased compared to a quantity of photo-generated carriers in a comparative SPAD sensor having the p-n junction formed in a planar surface. Accordingly, efficiency of the SPAD sensor is improved, and resolution for application of machine vision is improved.

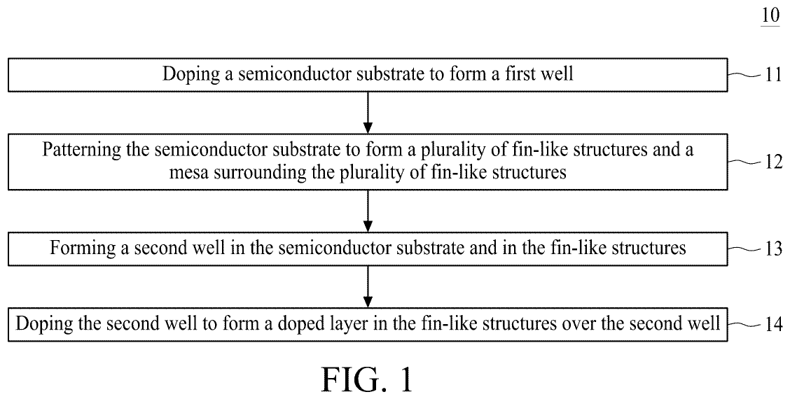

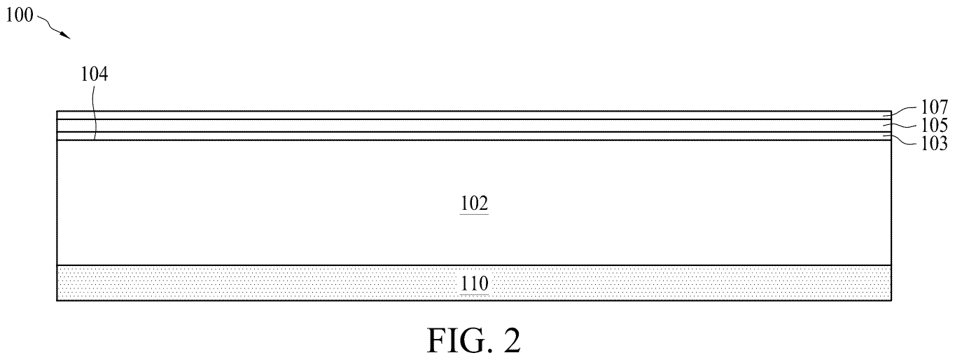

FIG. 1 is a flowchart representing a method for forming a SPAD sensor 10 in accordance with aspects of the present disclosure. Persons having ordinary skill in the art will understand that, in some embodiments, additional operations may be performed before, during or after the method 10, and that some of the operations described may be replaced or eliminated in some embodiments of the method 10. FIGS. 2 to 10 are schematic drawings illustrating the method of forming the SPAD sensor at various fabrication stages in accordance with some embodiments of the present disclosure.

In some embodiments, the SPAD sensors may be formed for front side illumination (FSI), meaning that the SPAD sensors are arranged to be photosensitive to light incident on a front surface of a substrate. For an image sensor including the SPAD sensors arranged for FSI, a majority of photon absorption occurs near the front surface of the substrate. In some alternative embodiments, the SPAD sensors are formed for back side illumination (BSI), meaning that the SPAD sensors are arranged to be photosensitive to light incident on a back surface of a substrate. For an image sensor including the SPAD sensors arranged for BSI, a majority of photon absorption occurs near the back surface of the substrate.

The method for forming the SPAD sensor 10 provided by the present disclosure can be performed to form the SPAD sensor for FSI or BSI. Further, the method for forming the SPAD sensor 10 can be integrated with planar device formation or non-planar device formation such as FinFET device formation and gate-all-around (GAA) device formation.

Referring to FIGS. 1 and 2, in some embodiments, the method 10 includes an operation 11, in which a first well 110 is formed in a semiconductor substrate 102. In some embodiments, the semiconductor substrate 102 may include any type of semiconductor body, for example a substrate formed of silicon, a material including silicon, a III-V compound semiconductor material such as silicon germanium (SiGe), gallium arsenide (GaS), or a silicon-on-insulator (SOI), but the disclosure is not limited thereto. In some embodiments, the forming of the first well 110 includes doping the semiconductor substrate 102. The first well 110 is formed in the semiconductor substrate 102 and separated from a surface 104 of the semiconductor substrate 102. In some embodiments, the first well 110 is therefore referred to as a deep well. In some embodiments, the first well 110 may include dopants of a first conductivity type, for example, an n-type. In such embodiments, the first well 110 may be referred to as a deep n well (DNW). In some embodiments, an epitaxial layer may be formed over the first well 110 to separate the first well 110 from the surface 104 of the semiconductor substrate 102.

Still referring to FIG. 2, in some embodiments, a pad oxide layer 103 may be formed prior to or after the forming of the first well 110. In some embodiments, a hard mask layer 105 may be formed over the pad oxide layer 103, and an anti-reflective coating (ARC) 107 may be formed over the hard mask layer 105.

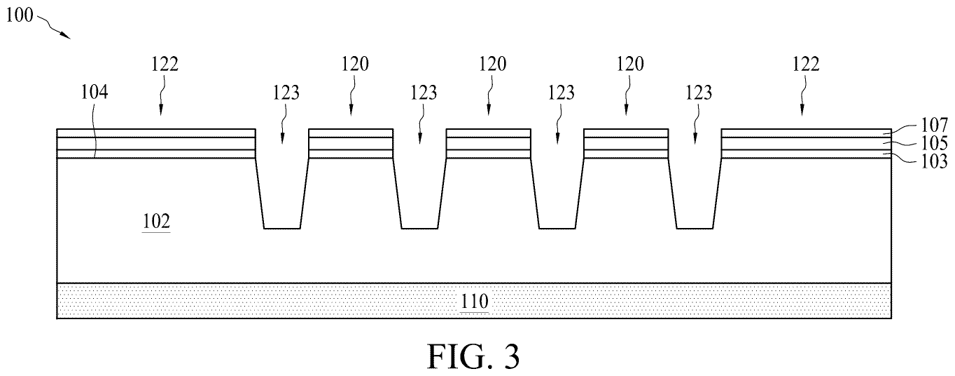

Referring to FIGS. 1 and 3, in some embodiments, the method 10 includes an operation 12, in which a plurality of fin-like structures 120 and a mesa 122 surrounding the plurality of fin-like structures 120 are formed over the semiconductor substrate 102. In some embodiments, the forming of the fin-like structures 120 and the mesa 122 includes patterning the semiconductor substrate 102 using suitable photolithography and etching operations. Further, the fin-like structures 120 are separated from each other by a plurality of recesses 123, and the fin-like structures 120 are also separated from the mesa by the recesses 123, as shown in FIG. 3. In some embodiments, a depth of the recess 123 may be between approximately 50 nanometers and approximately 50 micrometers, but the disclosure is not limited thereto. An aspect ratio of the recess 123 may be less than 6.2, but the disclosure is not limited thereto. In some comparative approaches, when the aspect ratio is greater than 6.2, a gap-filling result in subsequent operations may be adversely affected.

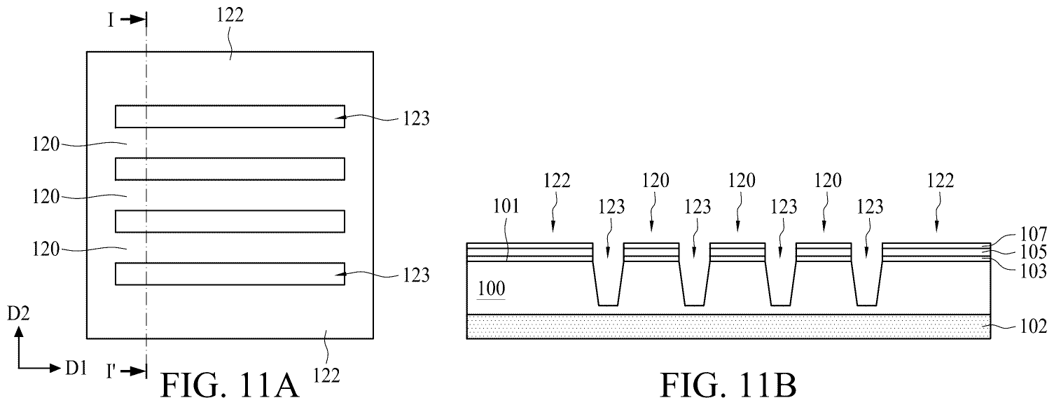

In some embodiments, the fin-like structures 120 may be periodically arranged. Please refer to FIGS. 11A and 11B, wherein FIG. 11A is a plan view of the semiconductor substrate 102 after the forming of the fin-like structures 120 and the mesa 122, and FIG. 11B is a cross-sectional view taken along a line I-I′ of FIG. 11A. As shown in FIGS. 11A and 11B, the fin-like structures 120 have a strip configuration extending in a direction D1 and arranged in a direction D2. The recesses 123 may extend in the direction D1, and may be arranged in the direction D2 in order to separate the fin-like structures 120 from each other.

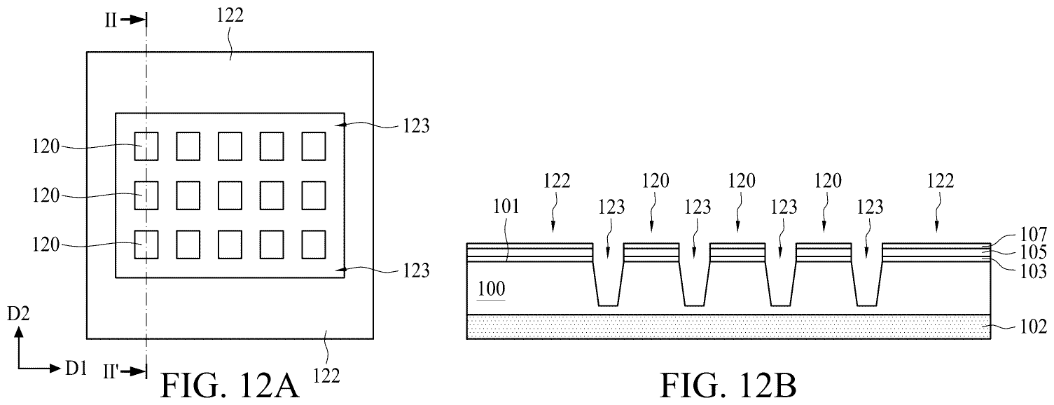

Please refer to FIGS. 12A and 12B, wherein FIG. 12A is a plan view of the semiconductor substrate 102 after the forming of the fin-like structures 120 and the mesa 122, and FIG. 12B is a cross-sectional view taken along a line II-II′ of FIG. 12A. As shown in FIGS. 12A and 12B, the fin-like structures 120 have a pillar configuration arranged in the first direction D1 and the second direction D2, while the recesses 123 are coupled to each other to form a grid configuration to separate the fin-like structures 120 from each other and from the mesa 122.

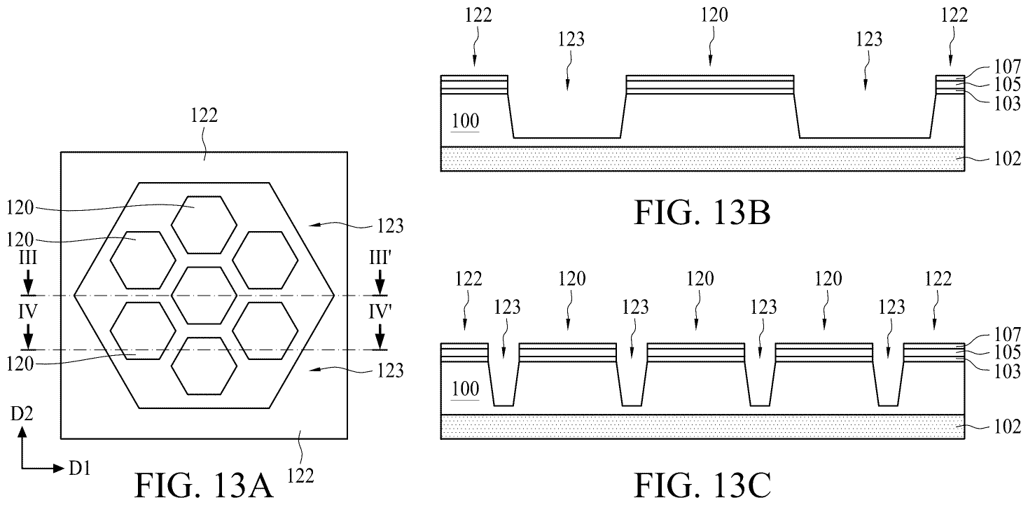

Please refer to FIGS. 13A to 13C, wherein FIG. 13A is a plan view of the semiconductor substrate 102 after the forming of the fin-like structures 120 and the mesa 122, FIG. 13B is a cross-sectional view taken along a line III-III′ of FIG. 13A, and FIG. 13C is a cross-sectional view taken along a line IV-IV′ of FIG. 13A. As shown in FIGS. 13A to 13C, the fin-like structures 120 have a hexagonal-pillar configuration periodically arranged, while the recesses 123 are coupled to each other to separate the fin-like structures 120 from each other and from the mesa 122.

It should be noted that the configurations and arrangements of the fin-like structures 120 can be modified according to product design; therefore, the abovementioned strip configuration and pillar configuration are exemplary provided, and are not a limitation.

In some embodiments, the ARC 107, the hard mask layer 105 and the pad oxide layer 103 are removed after the forming of the fin-like structures 120 and the mesa 122.

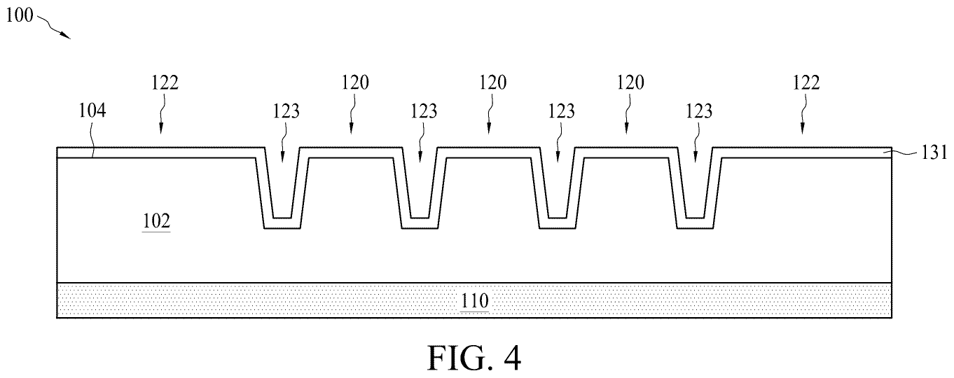

Referring to FIGS. 1 and FIGS. 4 to 6, in some embodiments, the method 10 includes an operation 13, in which a second well 130 is formed in the semiconductor substrate 102 and in each of the fin-like structures 120. In some embodiments, the operation 13 includes further operations. For example, a protection layer 131 may be formed over the semiconductor substrate 102. As shown in FIG. 4, the protection layer 131 may cover the mesa 122 and each of the fin-like structures 120. Further, the protection layer 131 may cover bottoms and sidewalls of the recesses 123. In some embodiments, the protection layer 131 may be a silicon oxide layer, but the disclosure is not limited thereto. In some embodiments, the protection layer 131 may be formed by a thermal operation. In other embodiments, the protection layer 131 may be formed by a suitable deposition, such as chemical vapor deposition (CVD), physical vapor deposition (PVD), plasma-enhanced CVD (PECVD), high-density plasma CVD (HDP-CVD), or sub-atmospheric CVD (SACVD), but the disclosure is not limited thereto. The forming of the protection layer 131 may help to mitigate damages to the fin-like structures 120 in subsequent operations.

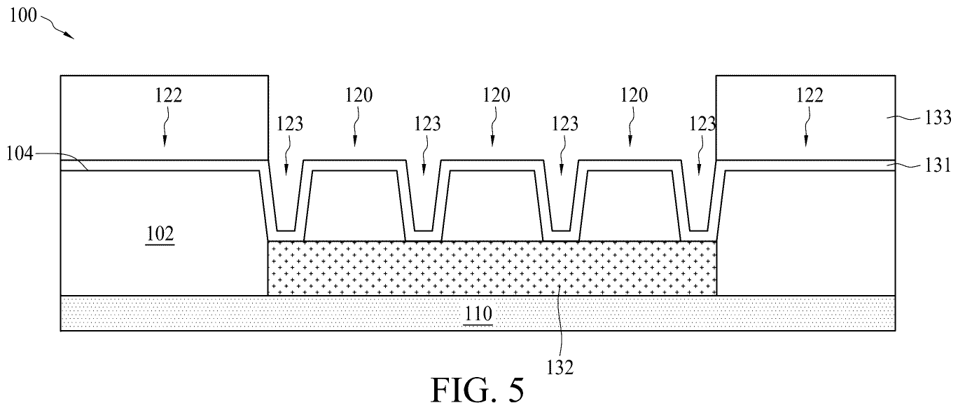

Referring to FIG. 5, in some embodiments, a patterned photoresist 133 is formed over the surface 104 of the semiconductor substrate 102. Further, the patterned photoresist 133 is formed to cover the mesa 122 and expose the fin-like structures 120. After the forming of the patterned photoresist 133, a well region 132 is formed in the semiconductor substrate 102. The forming of the well region 132 includes doping a portion of the semiconductor substrate 102 through the patterned photoresist 133. In some embodiments, an ion implantation is performed on the fin-like structures 120 exposed through the patterned photoresist 133. In some embodiments, an implant energy of the ion implantation may be between approximately 600 keV and approximately 2500 keV, but the disclosure is not limited thereto. As shown in FIG. 5, the well region 132 is formed under the fin-like structure 120 and over the first well 110 due to such implant energy. In some embodiments, the well region 132 may be in contact with the first well 110, but the disclosure is not limited thereto.

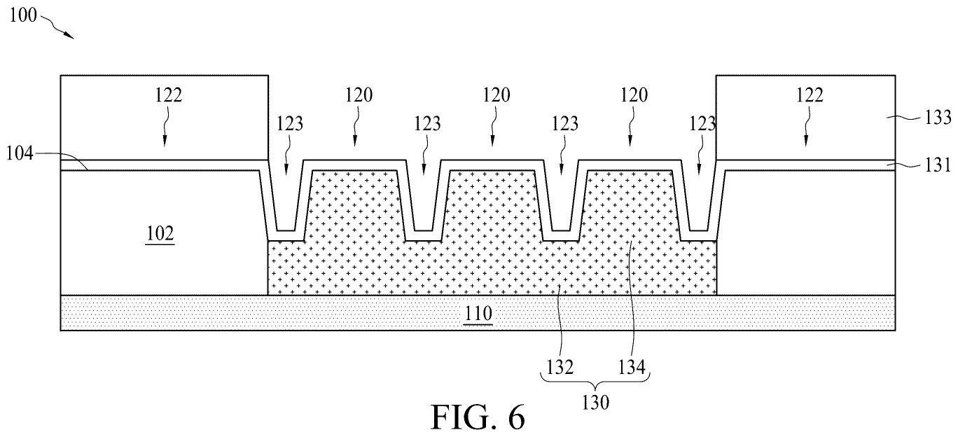

Referring to FIG. 6, another well region 134 is formed in each fin-like structure 120. The well regions 134 in the fin-like structures 120 are all coupled to the well region 132, thereby forming the second well 130. The well region 132 and the well regions 134 include a same conductivity type. Further, the first well 110 and the second well 130 include a same conductivity type, for example, the n type. In some embodiments, the first well 110 is referred to as the DNW, and the second well 130 is referred to as a SPAD N-well. In some embodiments, the forming of the well regions 134 include doping the fin-like structures 120 through the patterned photoresist 133. In some embodiments, an ion implantation is performed, wherein an implant energy of the ion implantation for forming the well region 134 is less than that of the ion implantation for forming the well region 132. In some embodiments, the implant energy of the ion implantation may be between approximately 60 keV and approximately 2500 keV, but the disclosure is not limited thereto. As shown in FIG. 6, the mesa 122 is protected from the ion implantations by the patterned photoresist 133, thus preventing formation of well regions 132 and 134 in the mesa 122. Accordingly, the second well 130 is confined under the fin-like structures 120 and the recesses 123, while the mesa 122 is substantially free of the dopants of the second well 130.

In some embodiments, a well can be formed in the mesa 122. The well may be an n-type well or a p-type well, depending on a type of the field-effective transistor (FET) device, when the FET device is needed. Additionally, the well in the mesa 122 may be formed prior to the forming of the second well 130 or after the forming of the second well 130, depending on process design.

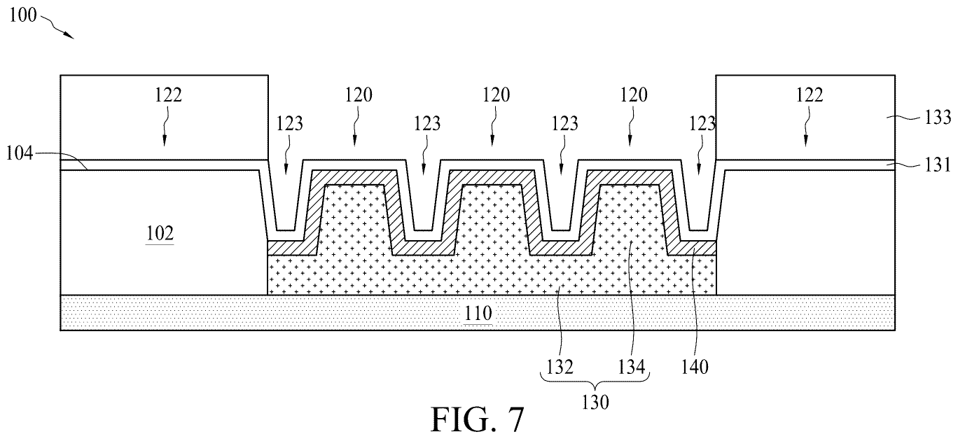

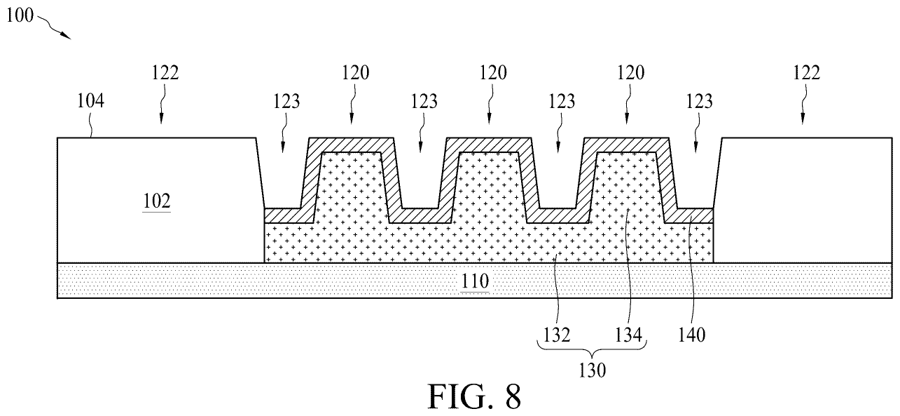

Referring to FIGS. 1 and 7, in some embodiments, the method 10 includes an operation 14, in which a doped layer 140 is formed in each fin-like structure 120. The forming of the doped layer 140 includes doping the second well 130. In some embodiments, an ion implantation is performed, wherein an implant energy of the ion implantation is less than that of the ion implantations for forming the first well 110 and the second well 130. In some embodiments, the implant energy for forming the doped layer 140 is between approximately 60 keV and approximately 2500 keV, but the disclosure is not limited thereto. Because the implant energy for forming the doped layer 140 is less than that of the ion implantations for forming the first well 110 and the second well 130, a depth of the doped layer 140 is less than that of the second well 130. In some embodiments, the doped layer 140 may be formed over the second well 130, and conformally formed along the wavy or non-planar surface of the plurality of fin-like structures 120, as shown in FIG. 7. Additionally, the doped layer 140 is in contact with the second well 130, but separated from the first well 110 by the second well 130. In some embodiments, the doped layer 140 includes dopants having a conductivity type complementary to that of the dopants in the first well 110 and the second well 130. For example, the doped layer 140 may include p-type dopants. In such embodiments, the doped layer 140 may be referred to as a SPAD P-well.

Referring to FIG. 8, the patterned photoresist 133 is removed from the semiconductor substrate 102 after the forming of the doped layer 140. Further, the protection layer 131 is removed from the semiconductor substrate 102 after the forming of the doped layer 140.

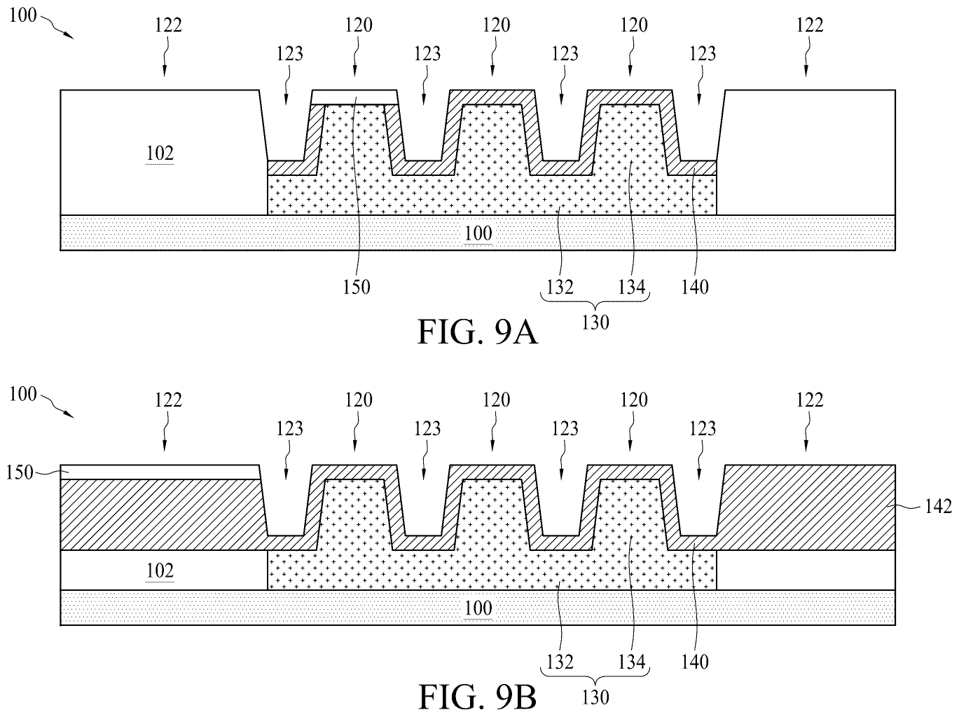

Please refer to FIGS. 9A and 9B, which are schematic drawings illustrating a stage subsequent to the removing of the protection layer 131 in accordance with various embodiments. In some embodiments, a doped region 150 may be formed over one of the fin-like structures 120 as shown in FIG. 9A, or formed over the mesa 122 as shown in FIG. 9B. In some embodiments, the forming of the doped region 150 includes doping the one of the fin-like structures 120 or doping the mesa 122. The doped region 150 and the doped layer 140 include a same conductivity type, i.e., the p-type. A dopant concentration of the doped region 150 is greater than a dopant concentration of the doped layer 140. In some embodiments, the doped region 150 is referred to as a heavily-doped region that is formed to provide an adequate ohmic contact with a connecting structure.

Additionally, referring to FIG. 9B, in some embodiments, when the doped region 150 is formed over the mesa 122, a well 142 may be formed before, during or after the forming of the doped layer 140. In some embodiments, the well 142 and the doped layer 140 may include a same conductivity type. In some embodiments, a dopant concentration of the well 142 may be equal to or less than the dopant concentration of the doped layer 140. In some embodiments, the dopant concentration of the doped region 150 is greater than the dopant concentration of the well 142.

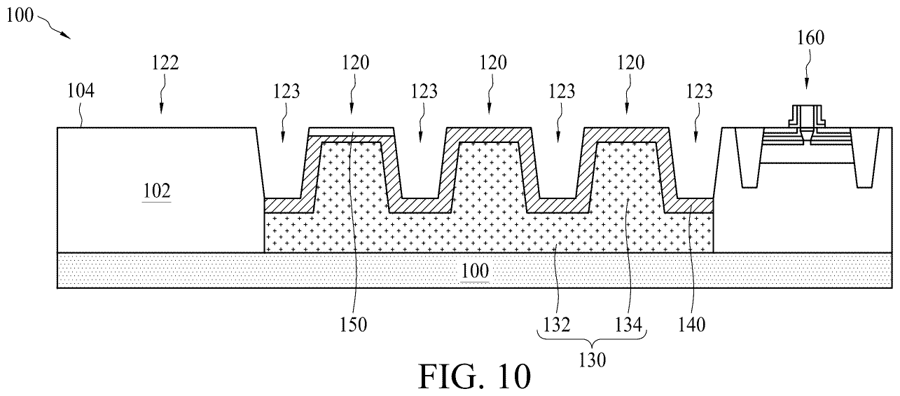

Referring to FIG. 10, in some embodiments, a FET device 160 may be formed over the mesa 122, but the disclosure is not limited thereto.

In accordance with some embodiments, a SPAD sensor 100 is provided. The SPAD sensor 100 includes a plurality of fin-like structures 120 disposed over a semiconductor substrate 102, a mesa 122 surrounding the fin-like structures 120, a first well 110, a second well 130, a doped layer 140, and a doped region 150. The first well 110 is disposed in the semiconductor substrate 102 and under the fin-like structures 120 and the mesa 122. The second well 130 is formed in the fin-like structures 120 and in the semiconductor substrate 102 under the fin-like structures 120. In some embodiments, the second well 130 may be in contact with the first well 110. The doped layer 140 is conformally formed with a wavy or non-planar configuration of the fin-like structures 120. Further, the doped region 140 is in contact with the second well 130. As mentioned above, the second well 130 may be referred to as a SPAD N-well, and the doped layer 140 may be referred to as a SPAD P-well. It should be noted that the SPAD N-well 130 and the SPAD P-well 140 provide a p-n junction where photo-generated carriers are formed. As shown in FIGS. 8 to 10, an area of the p-n junction, which is a multiplication junction region, is increased due to the wavy or non-planar configuration of the fin-like structures 120. Accordingly, a quantity of the photo-generated carriers generated in the p-n junction is increased, and thus performance of the SPAD sensor 100 is improved.

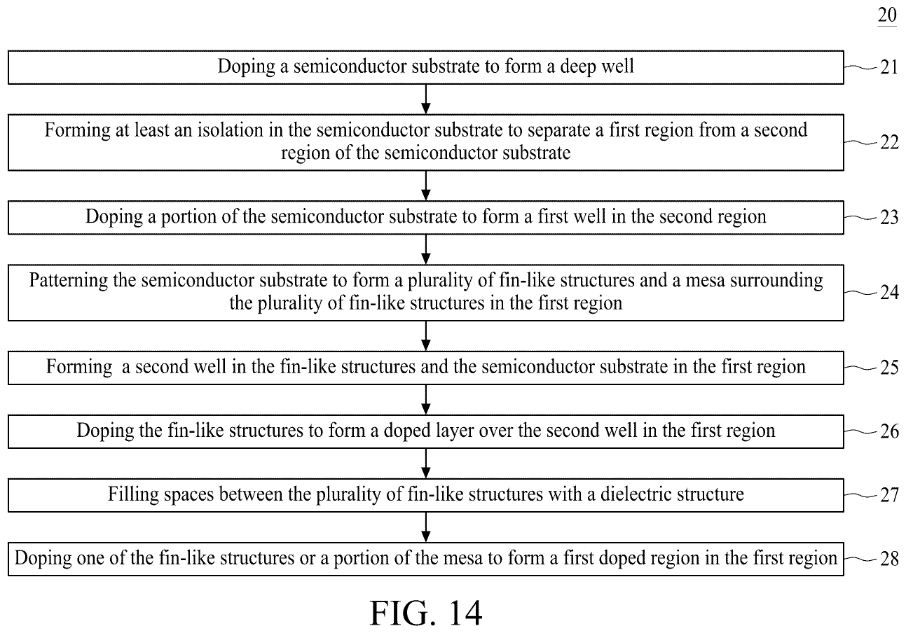

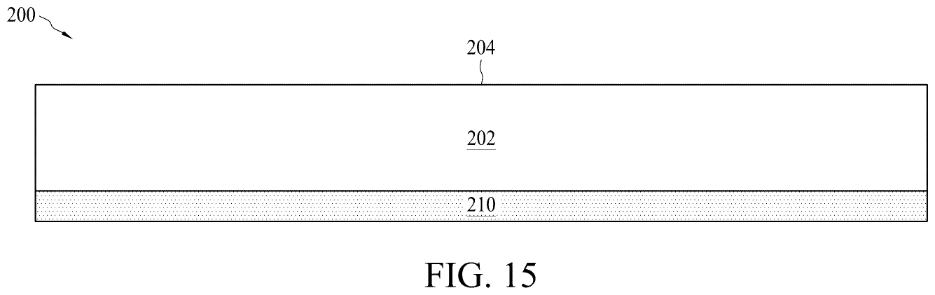

Please refer to FIG. 14, which is a flowchart representing a method 20 for forming a semiconductor structure 200 including a SPAD sensor 100 in accordance with aspects of the present disclosure. Persons having ordinary skill in the art will understand that, in some embodiments, additional operations may be performed before, during or after the method 20, and that some of the operations described may be replaced or eliminated in some embodiments, of the method 20. FIGS. 15 to 25B are schematic drawings illustrating the method 20 of forming the semiconductor structure 200 including the SPAD sensor 100 at various fabrication stages in accordance with some embodiments of the present disclosure.

Referring to FIGS. 14 and 15, in some embodiments, the method 20 includes an operation 21, in which a deep well 210 is formed in a semiconductor substrate 202. In some embodiments, the operation 21 is similar to operation 11. The semiconductor substrate 202 may be similar to the semiconductor substrate 102; therefore, repeated descriptions of details are omitted for brevity. The deep well 210 may include dopants of a first conductivity type such as an n type. In such embodiments, the deep well 210 may also be referred to as a deep n-well (DNW). As shown in FIG. 15, the deep well 210 is separated from a surface 204 of the semiconductor substrate 202.

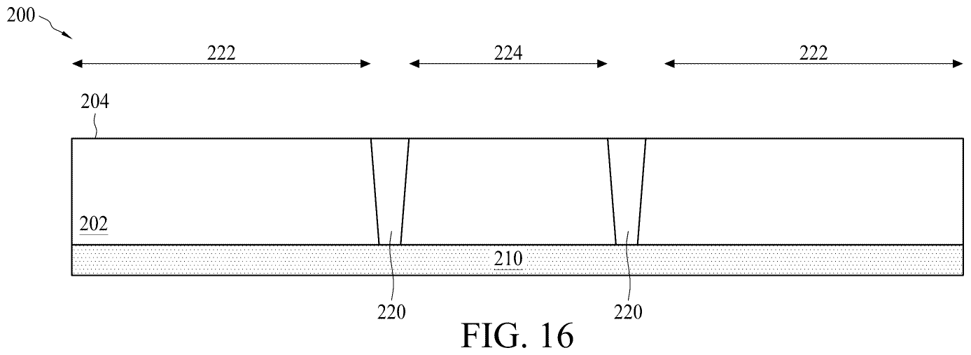

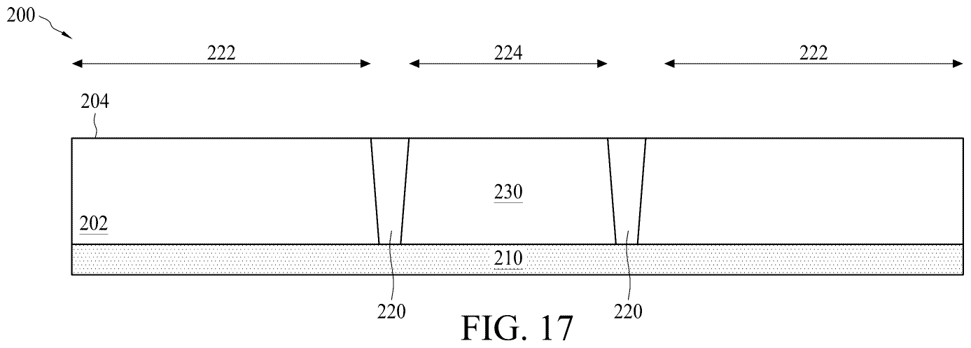

Referring to FIGS. 14 and 16, in some embodiments, the method 20 includes an operation 22, in which at least an isolation 220 is formed to define and separate a first region 222 and a second region 224 in the semiconductor substrate 202. In some embodiments, a bottom surface of the isolation 220 may be in contact with the deep well 210, but the disclosure is not limited thereto. In some embodiments, the isolation 220 is formed by etching recesses (not shown) in the semiconductor substrate 202 using a photolithography process, and filling the recesses with one or more dielectric materials. In some embodiments, the recesses are formed by forming a photoresist layer (not shown) over the semiconductor substrate 202, lithographically patterning the photoresist layer, and transferring the pattern into an upper portion of the semiconductor substrate 202 by an anisotropic etching operation, such as reactive ion etching (RIE) or plasma etching. The dielectric material is deposited by CVD or PVD. Excess dielectric material is then removed from above the surface of the semiconductor substrate 202, for example, by chemical mechanical planarization (CMP). After planarization, a top surface of the isolation 220 is aligned (i.e., coplanar) with the surface 204 of the semiconductor substrate 202. In some embodiments, the isolation 220 may include a field oxide formed by a thermal oxidation.

Referring to FIGS. 14 and 17, in some embodiments, the method 20 includes an operation 23, in which a well 230 is formed in the second region 224. In some embodiments, the forming of the well 230 includes doping a portion of the semiconductor substrate 202 in the second region 224. The first region 222 may be defined to accommodate the SPAD sensor 100. In some embodiments, the second region 224 may be defined to accommodate a logic device (not shown) or an input/output device (not shown), depending on product design. In some embodiments, the well 230 is a high-voltage N-well (HVNW), but the disclosure is not limited thereto.

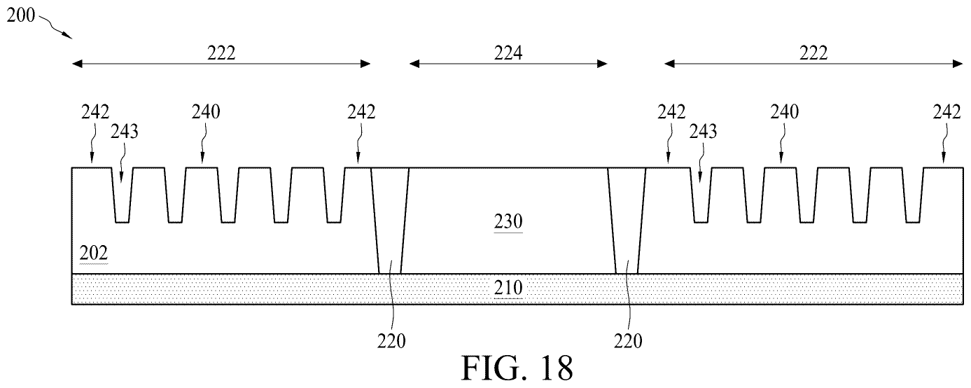

Referring to FIGS. 14 and 18, in some embodiments, the method 20 includes an operation 24, in which a plurality of fin-like structures 240 and a mesa 242 surrounding the plurality of fin-like structures 240 are formed over the semiconductor substrate 202 in the first region 222. In some embodiments, the operation 24 may be similar to the operation 12. The fin-like structures 240 and the mesa 242 are separated from each other by a plurality of recesses 243, as shown in FIG. 18. In some embodiments, a depth and an aspect ratio of the recess 243 may be similar to those of the recesses 123; therefore, such details are omitted for brevity. Further, configuration and arrangement of the fin-like structures 240 may be similar to those described above and shown in FIGS. 11A to 13C; therefore, such details are also omitted for brevity.

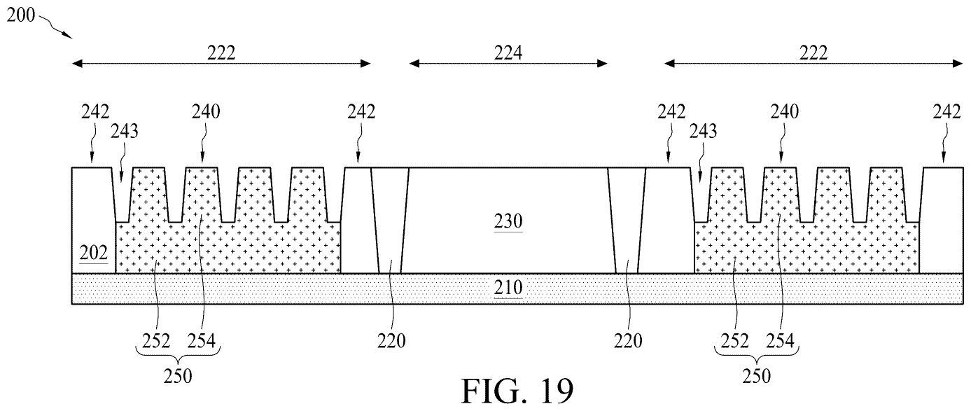

Referring to FIGS. 14 and 19, in some embodiments, the method 20 includes an operation 25, in which a well 250 is formed in the semiconductor substrate 202 and in each of the fin-like structures 240 in the first region 222. In some embodiments, the operation 25 is similar to the operation 13. In such embodiments, the operation 25 includes forming a protection layer (not shown) over the semiconductor substrate 202, and forming a patterned photoresist (not shown) over the mesa 242 in the first region 222 and over the well 230 in the second region 224. After the forming of the patterned photoresist, a well region 252 is formed in the semiconductor substrate 202. The forming of the well region 252 includes performing an ion implantation. The ion implantation for forming the well region 252 may be similar to that used to form the well region 132; therefore, those details are omitted for brevity. After the forming of the well region 252, a well region 254 is formed is formed in each fin-like structure 240. The forming of the well region 254 includes performing an ion implantation. The ion implantation for forming the well region 254 may be similar to that used to form the well region 134; therefore, details thereof are omitted for brevity. The well regions 254 in the fin-like structures 240 are all coupled to the well region 252. Thus, the well region 252 and the well regions 254 together form the well 250. The well region 252 and the well regions 254 include a same conductivity type. Further, the deep well 210 and the well 250 include a same conductivity type, for example, the n type. In some embodiments, the well 250 is referred to as a SPAD N-well.

In some embodiments, a depth of the well 230 and a depth of the well 250 may be similar, but the disclosure is not limited thereto. The well 230 and the well 250 include dopants of a same conductivity type. Further, the deep well 210, the well 230 and the well 250 include dopants of a same conductivity type, such as the n-type. A dopant concentration of the well 250 is greater than a dopant concentration of the deep well 210. In some embodiments, a dopant concentration of the well 230 is different from the dopant concentration of the well 250.

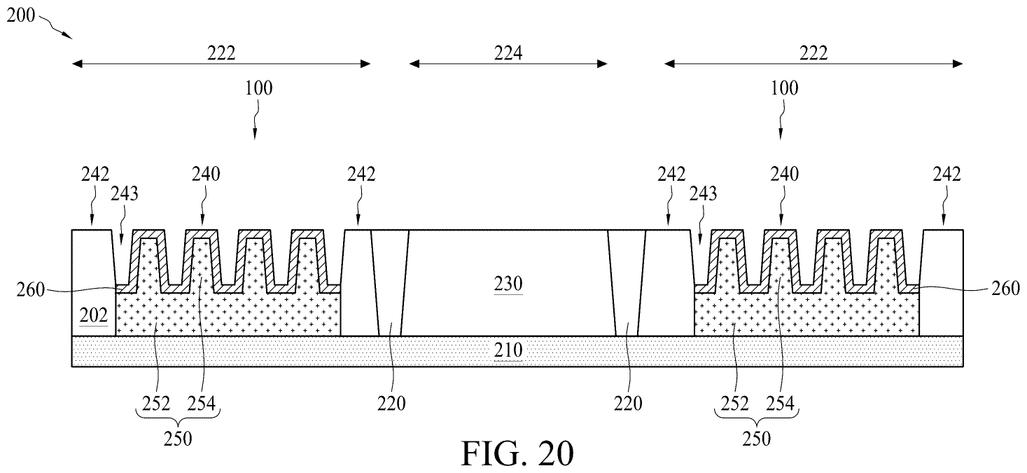

Referring to FIGS. 14 and 20, in some embodiments, the method 20 includes an operation 26, in which a doped layer 260 is formed in the semiconductor substrate 202 and in each fin-like structure 240. In some embodiments, the operation 26 is similar to the operation 14; therefore, details thereof are omitted for brevity. As shown in FIG. 20, a depth of the doped layer 260 is less than a depth of the well 250. In some embodiments, the doped layer 260 may be conformally formed over the well 250, and along the wavy or non-planar surface of the plurality of fin-like structures 240, as shown in FIG. 20. Additionally, the doped layer 260 is in contact with the well 250, but separated from the deep well 210 by the well 250. As mentioned above, the doped layer 260 includes dopants having a conductivity type complementary to that of the dopants in the deep well 210 and the well 250. For example, the doped layer 260 may include p-type dopants. In such embodiments, the doped layer 260 may be referred to as a SPAD P-well.

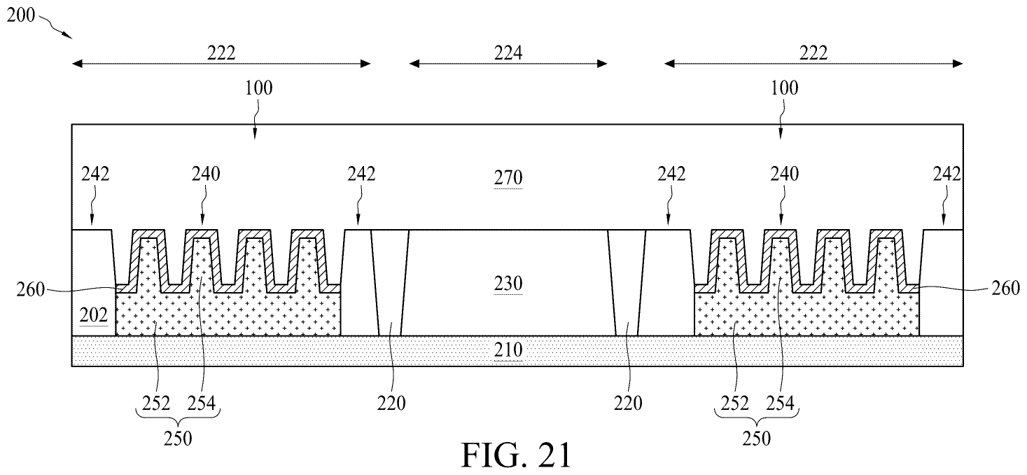

Referring to FIGS. 14 and 21, in some embodiments, the method 20 includes an operation 27, in which spaces between the fin-like structures 240 are filled with a dielectric structure 270. In some embodiments, the recesses 243 are filled with the dielectric structure 270. Accordingly, the fin-like structures 240 and the mesa 242 in the first region 222, and the well 230 in the second region 224 are embedded in and covered by the dielectric structure 270. In some embodiments, the dielectric structure 270 includes an inter-layer dielectric (ILD) layer. In some embodiments, the dielectric structure 270 includes and ILD layer and a contact etch stop layer (CESL), but the disclosure is not limited thereto. In some embodiments, the dielectric structure 270 is deposited using, for example but not limited thereto, CVD, PVD, PECVD or spin-on coating. In some embodiments, the dielectric structure 270 includes material having a low dielectric constant (low-k), such as a dielectric constant less than about 3.9. In some embodiments, the dielectric constant (also referred to as a k value) is less than about 3.0, or less than about 2.5. In some embodiments, the dielectric structure 270 includes spin-on-glass (SOG), fluoride-doped silicate glass (FSG), carbon doped silicon oxide, black diamondo (Applied Materials of Santa Clara, Calif.), Xerogel, Aerogel, amorphous fluorinated carbon, parylene, BCB (bis-benzocyclobutenes), SiLK (Dow Chemical, Midland, Mich.), polyimide, and/or other suitable materials.

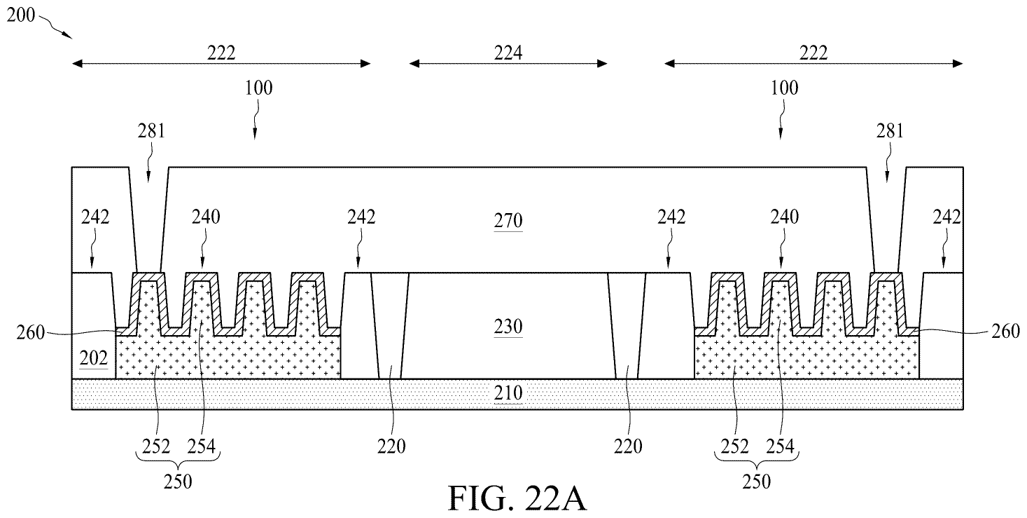

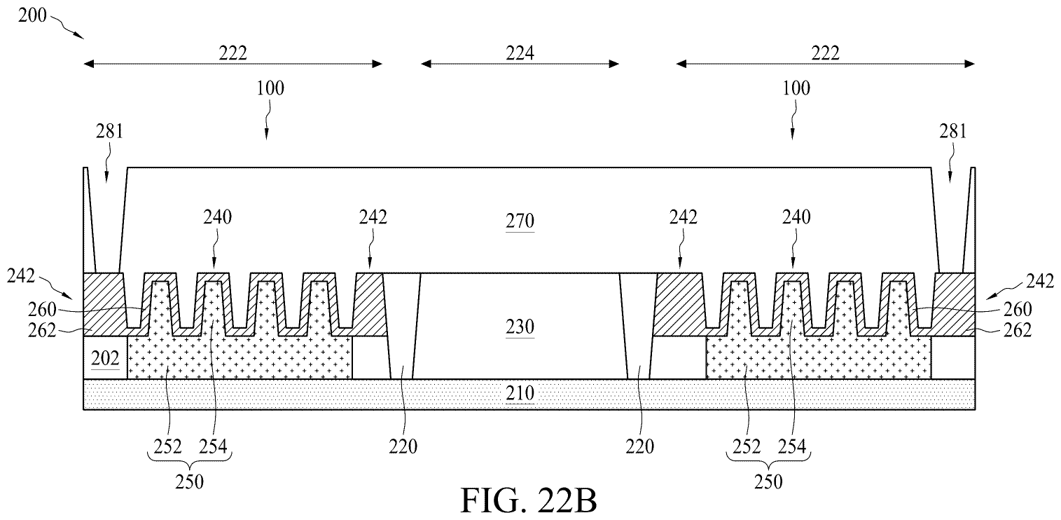

Referring to FIGS. 14, 22A, 22B, 23A and 23B, in some embodiments, the method 20 includes an operation 28, in which a doped region 280 is formed in the first region 222. In some embodiments, the operation 28 includes further operations. For example, an opening 281 is formed in the dielectric structure 270 to expose one of the plurality of fin-like structures 240 or to expose the mesa 242. In some embodiments, the forming of the opening 281 includes patterning the dielectric structure 270 using suitable photolithography and etching operations. Referring to FIG. 22A, in some embodiments, the opening 281 is formed in the dielectric structure 270 to expose the one of the fin-like structures 240. Accordingly, a portion of the doped layer 260 over the one of the plurality of fin-like structures 240 is exposed through a bottom of the opening 281. In other embodiments, as shown in FIG. 22B, the opening 281 is formed to expose the mesa 242. It should be noted that, in those embodiments in which the opening 281 is formed to expose the mesa 242, a well 262 may be formed in the mesa 242 prior to the forming of the dielectric structure 270, though not shown. In such embodiments, the well 262 is exposed through the bottom of the opening 281, as shown in FIG. 22B.

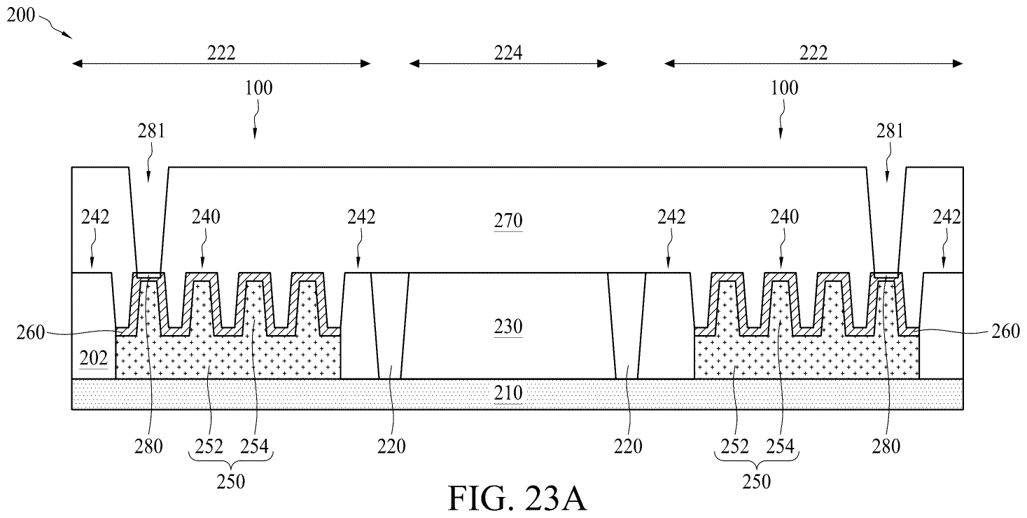

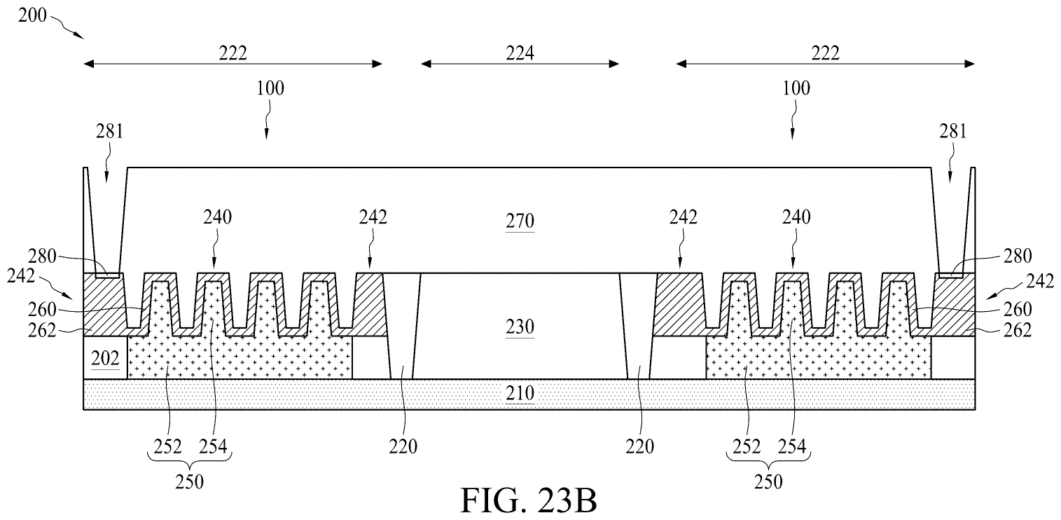

In some embodiments, the doped region 280 is formed in the bottom of the opening 281. In some embodiments, the forming of the doped region 280 includes doping the fin-like structure 240 exposed through the opening 281. Further, the doped region 280 is formed over the portion of the doped layer 260 exposed through the bottom of the opening 281, as shown in FIG. 23A. The doped region 280 and the doped layer 260 include a same conductivity type, i.e., the p-type. A dopant concentration of the doped region 280 is greater than a dopant concentration of the doped layer 260. In such embodiments, the doped region 280 is separated from the well 250 by the doped layer 260. Referring to FIG. 23B, in some embodiments, the forming of the doped region 280 includes doping the portion of the mesa 262 exposed through the opening 281. Further, the doped region 280 is formed over a portion of the well 262 exposed through the bottom of the opening 281. The doped region 280 and the well 262 include a same conductivity type, i.e., the p type. The dopant concentration of the doped region 280 is greater than a dopant concentration of the well 262. In some embodiments, the doped region 280 is referred to as a heavily-doped region that is formed to provide an adequate ohmic contact with a connecting structure.

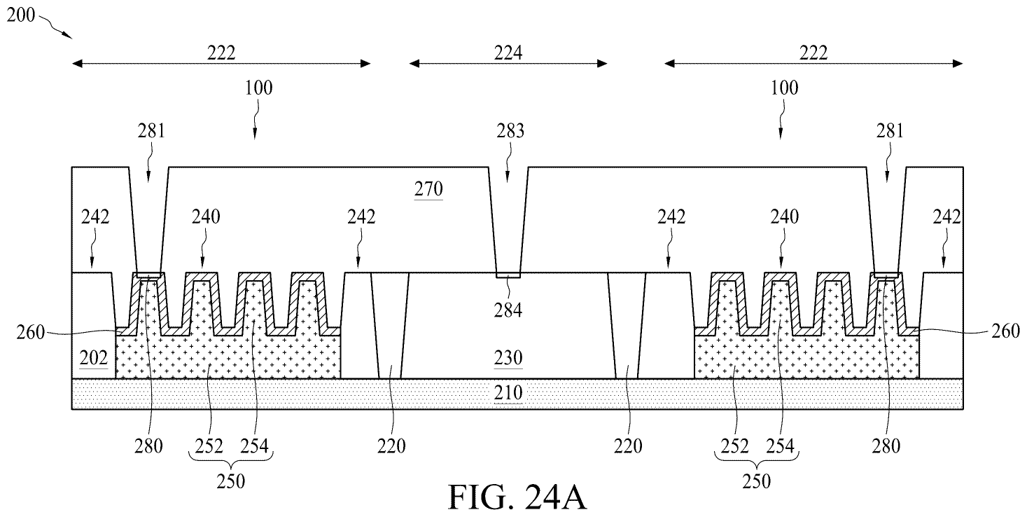

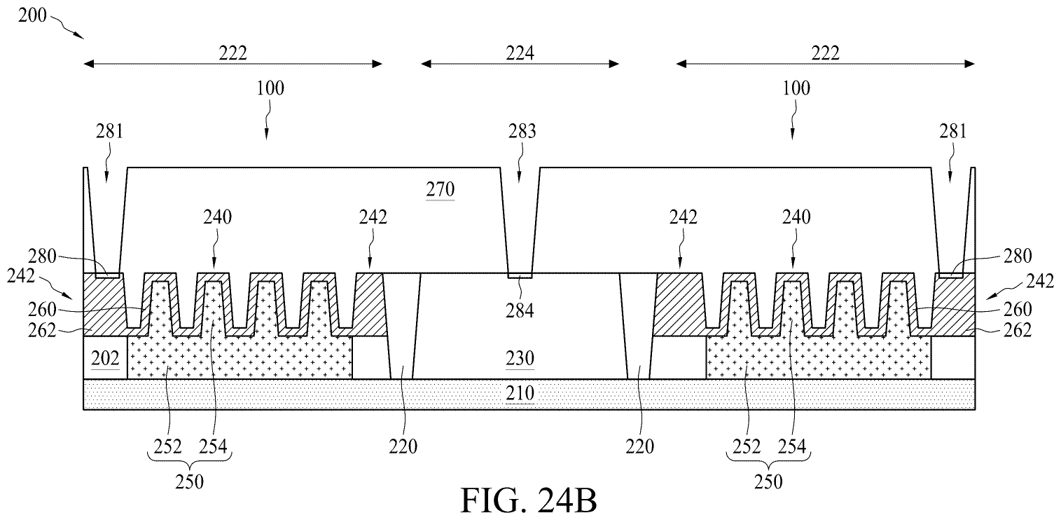

Referring to FIGS. 24A and 24B, in some embodiments, another opening 283 is formed in the dielectric structure 270 in the second region 224. The opening 283 may expose a portion of the well 230 in the second region 224. Further, another doped region 284 is formed over the portion of the well 230 exposed through a bottom of the opening 283. In some embodiments, the forming of the doped region 284 includes doping a portion of the semiconductor substrate 202 in the second region 204 that is exposed through the opening 283. In some embodiments, the doped region 284 and the well 230 include a same conductivity type, i.e., the n-type. A dopant concentration of the doped region 284 is greater than the dopant concentration of the well 230. In some embodiments, the doped region 284 is referred to as a heavily-doped region that is formed to provide an adequate ohmic contact with a connecting structure. In some embodiments, the forming of the opening 283 and the forming of the doped region 284 are performed after the forming of the opening 281 and the doped region 280, as shown in FIGS. 24A and 24B, but the disclosure is not limited thereto. In some alternative embodiments, the opening 283 and the doped region 284 may be formed before the forming of the opening 281 and the doped region 280, though not shown.

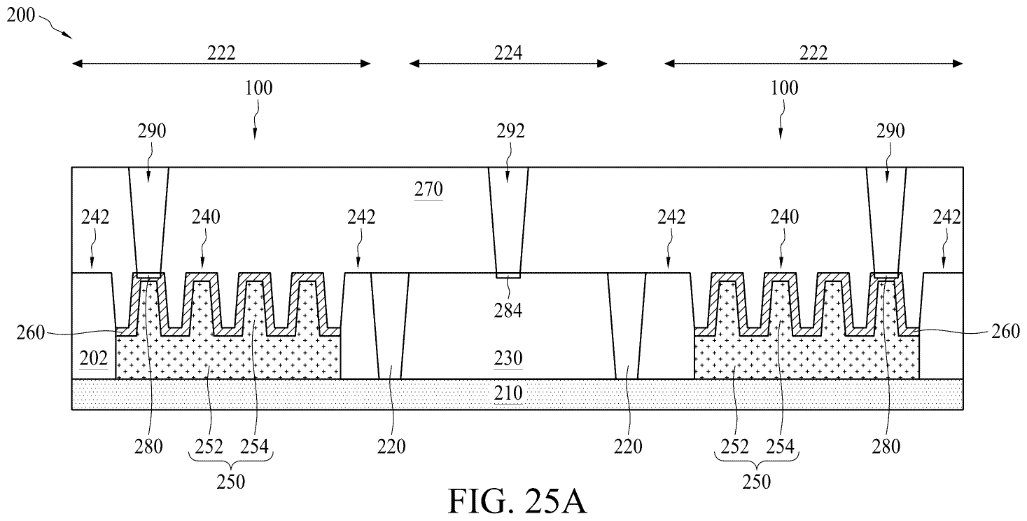

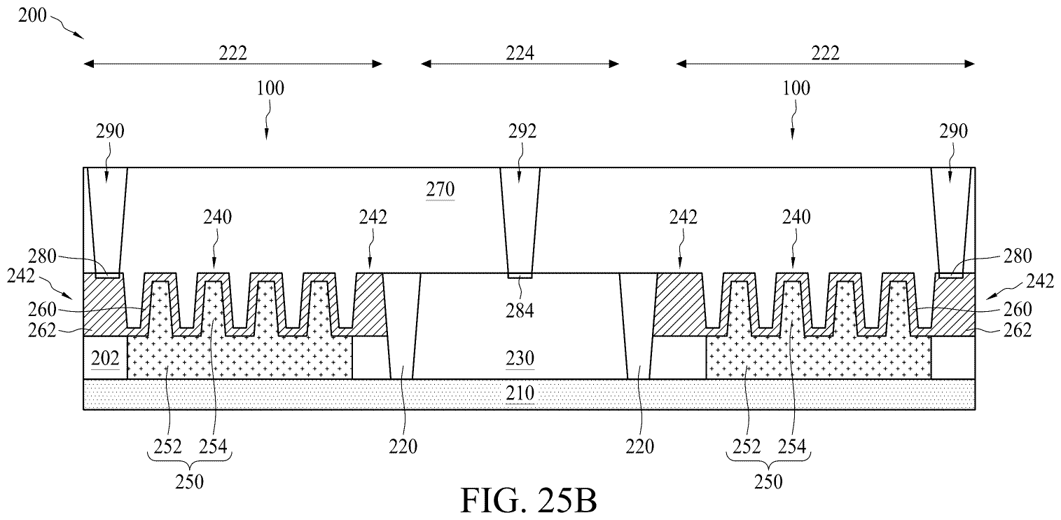

Referring to FIGS. 25A and 25B, in some embodiments, the method 20 further include forming a connecting structure 290 in the first region 222, and a connecting structure 292 in the second region 224. As shown in FIG. 25A, in some embodiments, the connecting structure 290 is coupled to the doped region 280 formed over the doped layer 260 in one of the fin-like structures 240 in the first region 222, and the connecting structure 292 is coupled to the doped region 284 formed over the well 230 in the second region 224. As shown in FIG. 25B, in some embodiments, the connecting structure 290 is coupled to the doped region 280 formed over the well 262 in the mesa 242 in the first region 222, and the connecting structure 292 is coupled to the doped region 284 formed over the well 230 in the second region 224. Accordingly, the connecting structure 290 forms an ohmic contact with the corresponding doped region 280, and the connecting structure 292 forms an ohmic contact with the corresponding doped region 284. The connecting structures 290 and 292 may be referred to as contact plugs that connect the SPAD sensor 100 to overlying metallization layers (not shown). In some embodiments, the connecting structures 290 and 292 include a conductive material such as, for example, copper, tungsten, aluminum, or an alloy thereof. In some embodiments, the connecting structures 290 and 292 also include a barrier/adhesion liner (not shown) to prevent diffusion and to provide better adhesion for the connecting structures 290 and 292. In some embodiments, the barrier/adhesion liner includes titanium nitride (TiN). Accordingly, the semiconductor structure 200 including the SPAD sensor 100 is obtained.

Accordingly, the present disclosure provides a SPAD sensor having a plurality of fin-like structures where a p-n junction is formed. In some embodiments, the p-n junction is formed in the fin-like structures, which have a wavy or non-planar configuration. Accordingly, an area of the p-n junction is increased. As a result, a quantity of photo-generated carriers generated in the p-n junction per unit area is increased compared with that of a comparative SPAD sensor having the p-n junction formed in a planar surface. Accordingly, efficiency of the SPAD sensor is improved, and resolution for application of machine vision is improved.

In accordance with one embodiment of the present disclosure, a method of forming a SPAD sensor is provided. The method includes following operations. A semiconductor substrate is doped to form a first well. The semiconductor substrate is patterned to form a plurality of fin-like structures and a mesa surrounding the fin-like structures. A second well is formed in each of the fin-like structures. The second well is doped to form a doped layer in the fin-like structures and over the second well.

In accordance with one embodiment of the present disclosure, a method for forming a semiconductor structure including a SPAD sensor is provided. The method includes following operations. A semiconductor substrate is doped to form a deep well. At least an isolation is formed in the semiconductor substrate. The isolation separates a first region of the semiconductor substrate from a second region of the semiconductor substrate. A portion of the semiconductor substrate is doped to form a first well is formed in the second region. The semiconductor substrate is patterned to form a plurality of fin-like structures and a mesa surrounding the plurality of fin-like structures in the first region. A second well is formed in the fin-like structures and the semiconductor substrate in the first region. The fin-like structures are doped to form a doped layer over the second well in the first region. Spaces between the plurality of fin-like structures are filled with a dielectric structure. One of the fin-like structures or the mesa is doped to form a first doped region in the first region.

In accordance with one embodiment of the present disclosure, a semiconductor structure including a SPAD sensor is provided. The semiconductor structure includes a plurality of fin-like structures disposed over a semiconductor substrate, a mesa surrounding the plurality of fin-like structures over the semiconductor substrate, a first well disposed in the semiconductor substrate, a second well disposed in the fin-like structures over the first well, and a doped layer disposed in the fin-like structures and over the second well.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a single-photon avalanche diode (SPAD) sensor, comprising:
doping a semiconductor substrate to form a first well;
patterning the semiconductor substrate to form a plurality of fin-like structures and a mesa surrounding the plurality of fin-like structures;
forming a second well in the semiconductor substrate and in the fin-like structures; and
doping the second well to form a doped layer in the fin-like structures and over the second well.

2. The method of claim 1, wherein the first well and the second well include a first conductivity type, and the doped layer includes a second conductivity type complementary to the first conductivity type.

3. The method of claim 1, further comprising forming a protection layer over the plurality of fin-like structures prior to the forming of the second well.

4. The method of claim 3, further comprising removing the protection layer after the forming of the doped layer.

5. The method of claim 1, wherein the forming of the second well further comprises:
doping a portion of the semiconductor substrate to form a first well region under the plurality of fin-like structures; and
doping the fin-like structures to form a second well region coupled to the first well region.

6. The method of claim 1, further comprising doping one of the plurality of fin-like structures to form a doped region, wherein the doped region and the doped layer comprise a same conductivity type.

7. The method of claim 1, further comprising doping the mesa to form a doped region, wherein the doped region and the doped layer comprise a same conductivity type.

8. A method for forming a semiconductor structure including a SPAD sensor, comprising:
doping a semiconductor substrate to form a deep well;
forming at least an isolation in the semiconductor substrate to separate a first region from a second region of the semiconductor substrate;
doping a portion of the semiconductor substrate to form a first well in the second region;
patterning the semiconductor substrate to form a plurality of fin-like structures and a mesa surrounding the plurality of fin-like structures in the first region;
forming a second well in the fin-like structures and the semiconductor substrate in the first region;
doping the fin-like structures to form a doped layer over the second well in the first region;
filling spaces between the plurality of fin-like structures with a dielectric structure; and
doping one of the fin-like structures or a portion of the mesa to form a first doped region in the first region.

9. The method of claim 8, wherein the deep well, the first well and the second well comprise a first conductivity type, and the doped layer and the first doped region comprise a second conductivity type complementary to the first conductivity type.

10. The method of claim 9, wherein a dopant concentration of the first doped region is greater than a dopant concentration of the doped layer.

11. The method of claim 8, further comprising patterning the dielectric structure to form an opening exposing the one of the plurality of fin-like structures or the portion of the mesa, wherein the first doped region is formed in the one of the plurality of fin-like structures exposed through the opening or in the portion of the mesa exposed through the opening.

12. The method of claim 11, further comprising forming a connecting structure in the opening, wherein the connecting structure is coupled to the first doped region.

13. The method of claim 8, further comprising:
doping a portion of the semiconductor substrate to form a second doped region over the first well in the second region; and
forming a connecting structure coupled to the second doped region,
wherein the first well and the second doped region comprise a same conductivity type.

14. The method of claim 13, wherein a dopant concentration of the second doped region is greater than a dopant concentration of the first well.

15. A semiconductor structure including a SPAD sensor comprising:
a plurality of fin-like structures disposed over a semiconductor substrate;
a mesa surrounding the plurality of fin-like structures over the semiconductor substrate;
a first well in the semiconductor substrate;
a second well in the fin-like structures over the first well and in the semiconductor substrate under the plurality of fin-like structures; and
a doped layer disposed in the plurality of fin-like structures and over the second well.

16. The semiconductor structure of claim 15, wherein the first well and the second well comprise a first conductivity type, and the doped layer comprises a second conductivity type complementary to the first conductivity type.

17. The semiconductor structure of claim 15, further comprising a doped region disposed over one of the plurality of fin-like structures or over the mesa, wherein the doped region and the doped layer comprise a same conductivity type.

18. The semiconductor structure of claim 17, wherein a dopant concentration of the doped region is greater than a dopant concentration of the doped layer.

19. The semiconductor structure of claim 17, further comprising a connecting structure coupled to the doped region.

20. The semiconductor structure of claim 15, wherein the plurality of fin-like structures are periodically arranged over the semiconductor substrate.
